(19) United States
(12) Patent Application Publication
(10) Pub. No.: US 2024/0210462 A1
(43) Pub. Date: Jun. 27, 2024

(54) TWO-PHASE THERMAL TEST APPARATUSES AND METHODS

(71) Applicant: Advantest Corporation, Tokyo (JP)

(72) Inventors: Peter Weixiang ZHENG, San Jose, CA (US); James Hastings, San Jose, CA (US)

(21) Appl. No.: 18/381,574

(22) Filed: Oct. 18, 2023

Related U.S. Application Data
(60) Provisional application No. 63/435,184, filed on Dec. 23, 2022.

(51) Int. Cl. G01R 31/26

(52) U.S. Cl. CPC G01R 31/2642

(57) ABSTRACT

A two-phase thermal system to provide cooling and heating for device testing. The two-phase thermal system utilizes a refrigeration system to cool one or more devices under test (DUTs) in a cooling mode, and heat the one or more DUTs in a heating mode. The available heat content of the hot gas from the compressor is greater than the evaporator cooling capacity of the refrigeration system, and therefore the two-phase thermal system can be utilized to both cool and heat the one or more DUTs.

### CROSS-REFERENCE TO RELATED APPLICATIONS

This application claims the benefit of U.S. Provisional Patent Application No. 63/435,184 filed Dec. 23, 2022, which is incorporated herein in its entirety.

### BACKGROUND

The testing of semiconductor devices and other devices under test (DUTs) often require heating and cooling to test the semiconductor devices at different temperatures. In the conventional art, the cooling for DUTs is provided by cold air, liquid or refrigerant. The heating for DUTs is separately provided by hot air or liquid from a heater.

In the conventional art, cooling is provided to a DUT through a thermal head. Cold air, liquid or refrigerant can be circulated through the thermal head. Heat is transferred from the DUT through the thermal head to the air, liquid or refrigerant flowing through the thermal head. The heated air, liquid or refrigerant than passes through a heat exchanger to cool the air liquid or refrigerant before it returns to the thermal head as cold air liquid or refrigerant.

For example, in a refrigerant system, the thermal head functions as an evaporator where the refrigerant in a gaseous form is cold and absorbs heat transmitted from the device under test to the thermal head. The thermal head defines a flow channel for passage of the refrigerant so as to cause cooling of the device under test. The gaseous refrigerant flows out of the thermal head to the compressor where it is compressed to a high pressure state that further increases the temperature of the refrigerant. The hot refrigerant flows to the condenser where heat from the hot refrigerant is removed, and the refrigerant is converted to a liquid state. The liquid refrigerant then flows through an expansion valve, where the pressure of the refrigerant is reduced, which also reduces the temperature of the refrigerant. The cold refrigerant then passes through the thermal head again to provide additional cooling of the device under test. The pressure and flow rate of the refrigerant is controlled to control the cooling of the device under test.

When both cooling and heating of the DUT is implemented for testing, one or more heaters are coupled to thermal head opposite the DUT. The combination of the heating system and cooling system are for the most part two separate system and tend to counteract each other. Therefore, there is a need for improved techniques for heating and cooling DUTs during testing.

### SUMMARY OF THE INVENTION

The present technology may best be understood by referring to the following description and accompanying drawings that are used to illustrate embodiments of the present technology directed toward two-phase thermal test apparatuses and methods.

In one embodiment, a two-phase thermal system for controlling thermal cycles of a device under test (DUT) includes a compressor, a condenser, an evaporator, a first set of control valves and a second set of control valves. The evaporator is configured for thermally coupling to one or more DUTs. The first set of control valves are configured to regulate the addition of refrigerant liquid from the condenser and refrigerant hot gas from the compressor to suction refrigerant from the evaporator. The second set of control valves are configured to regulate the supply of the refrigerant liquid from the condenser and the refrigerant hot gas from the compressor to the evaporator.

In another embodiment, a test system can include a condensing unit and a plurality of test sites. The condensing unit can include a compressor, a condenser and a first set of control valves. The first set of control valves can be configured to regulate the addition of refrigerant liquid from the condenser and refrigerant hot gas from the compressor to suction refrigerant from the evaporator. Each of the plurality of test sites can include an evaporator and a second set of control valves. The evaporator can be configured for thermally coupling to a device under test. The second set of control valves can be configured to regulate the supply of the refrigerant liquid from the condenser and the refrigerant hot gas from the compressor to the evaporator.

In yet another embodiment, a test system thermal control method can include determining a plurality of thermal cycle events. The method can further include regulating operation of a condenser, a compressor and one or more control valves to cool one or more devices under test during one or more cooling cycles of the plurality of thermal cycle events. The method can also include regulating operation of the condenser, the compressor and the one or more control valves to heat the one or more devices under test during one or more heating cycles of the plurality of thermal cycle events.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

Embodiments of the present technology are illustrated by way of example and not by way of limitation, in the figures of the accompanying drawings and in which like reference numerals refer to similar elements and in which:

FIG. 1 shows a test system, in accordance with aspects of the present technology.

FIG. 2 shows a test system thermal control method, in accordance with aspects of the present technology.

FIG. 3 shows a test system, in accordance with aspects of the present technology.

FIG. 4 shows a relationship between enthalpy and pressure for a DUT cooling cycle, according to the conventional art.

FIG. 5 shows a relationship between enthalpy and pressure for DUT cooling and heating cycles, according to the present technology.

### DETAILED DESCRIPTION

Reference will now be made in detail to the embodiments of the present technology, examples of which are illustrated in the accompanying drawings. While the present technology will be described in conjunction with these embodiments, it will be understood that they are not intended to limit the invention to these embodiments. On the contrary, the invention is intended to cover alternatives, modifications and equivalents. Furthermore, in the following detailed description of the present technology, numerous specific details are set forth in order to provide a thorough understanding of the present technology. However, it is understood that the present technology may be practiced without these specific details. In other instances, well-known methods, procedures, components, and circuits have not been described in detail as not to unnecessarily obscure aspects of the present technology.

Some embodiments of the present technology which follow are presented in terms of routines, modules, logic blocks, and other symbolic representations of operations on data within one or more electronic devices. The descriptions and representations are the means used by those skilled in the art to most effectively convey the substance of their work to others skilled in the art. A routine, module, logic block and/or the like, is herein, and generally, conceived to be a self-consistent sequence of processes or instructions leading to a desired result. The processes are those including physical manipulations of physical quantities. Usually, though not necessarily, these physical manipulations take the form of electric or magnetic signals capable of being stored, transferred, compared and otherwise manipulated in an electronic device. For reasons of convenience, and with reference to common usage, these signals are referred to as data, bits, values, elements, symbols, characters, terms, numbers, strings, and/or the like with reference to embodiments of the present technology.

It should be borne in mind, however, that these terms are to be interpreted as referencing physical manipulations and quantities and are merely convenient labels and are to be interpreted further in view of terms commonly used in the art. Unless specifically stated otherwise as apparent from the following discussion, it is understood that through discussions of the present technology, discussions utilizing the terms such as “receiving,” and/or the like, refer to the actions and processes of an electronic device such as an electronic computing device that manipulates and transforms data. The data is represented as physical (e.g., electronic) quantities within the electronic device's logic circuits, registers, memories and/or the like, and is transformed into other data similarly represented as physical quantities within the electronic device.

In this application, the use of the disjunctive is intended to include the conjunctive. The use of definite or indefinite articles is not intended to indicate cardinality. In particular, a reference to “the” object or “a” object is intended to denote also one of a possible plurality of such objects. The use of the terms “comprises,” “comprising,” “includes,” “including” and the like specify the presence of stated elements, but do not preclude the presence or addition of one or more other elements and or groups thereof. It is also to be understood that although the terms first, second, etc. may be used herein to describe various elements, such elements should not be limited by these terms. These terms are used herein to distinguish one element from another. For example, a first element could be termed a second element, and similarly a second element could be termed a first element, without departing from the scope of embodiments. It is also to be understood that when an element is referred to as being “coupled” to another element, it may be directly or indirectly connected to the other element, or an intervening element may be present. In contrast, when an element is referred to as being “directly connected” to another element, there are not intervening elements present. It is also to be understood that the term “and or” includes any and all combinations of one or more of the associated elements. It is also to be understood that the phraseology and terminology used herein is for the purpose of description and should not be regarded as limiting.

Embodiments of the present technology are directed toward the use of a two-phase thermal system to provide cooling and heating for semiconductor device testing. Embodiments of the present technology utilize a refrigeration system to cool one or more devices under test (DUTs) in a cooling mode, and heat the one or more DUTs in a heating mode. In a cooling mode, liquid refrigerant from a condenser of the refrigeration system is used for cooling the one or more DUTs. In the heating mode, hot air or gas from a compressor of the refrigeration system is used for heating the one or more DUTs. The available heat content of the hot gas from the compressor is greater than the evaporator cooling capacity of the refrigeration system, and therefore the two-phase thermal system can be utilized to both cool and heat the one or more DUTs.

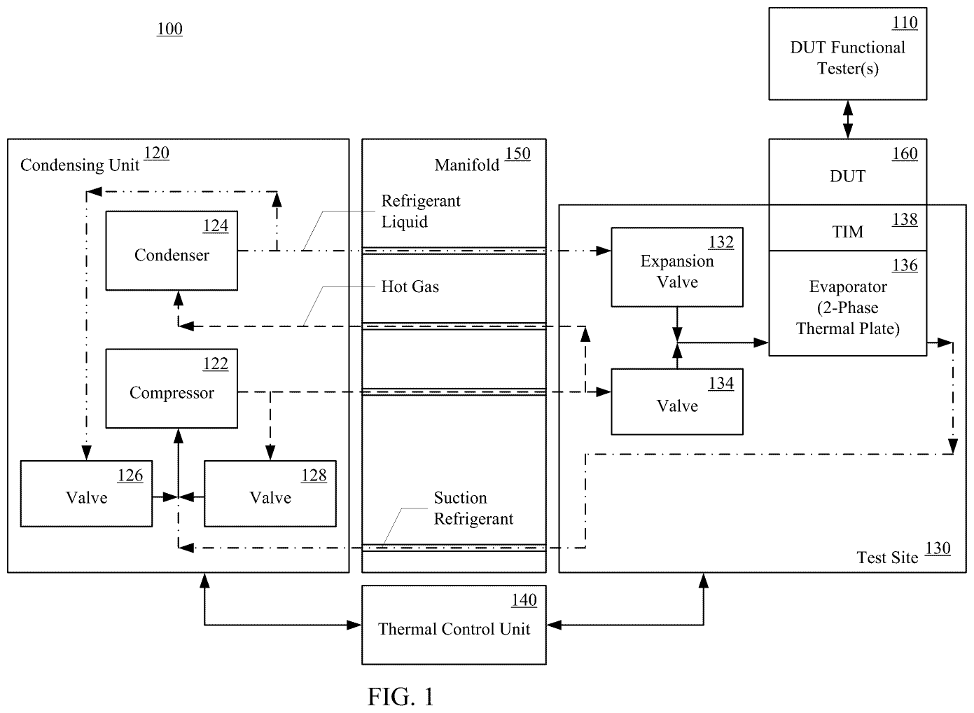

Referring now to FIG. 1, a test system, in accordance with aspects of the present technology, is shown. The test system 100 can include one or more functional testers 110 and a two-phase thermal sub-system 120-150. The one or more functional testers 110 can be coupled to a device under test (DUT) 160 to perform one or more test of one or more functions of the DUT 120. For example, the functional tester 110 can be coupled to a semiconductor device under tests, such as but not limited to a memory device, a processing unit or the like, to perform one or more tests, such as but not limited to performing various memory access functions, one or more computation functions and or the like, of the semiconductor device.

The two-phase thermal sub-system 120-150 can be configured to cool the DUT 160 in a cooling mode, and heat the DUT 160 in a heating mode during one or more of the functional tests of the DUT 160. The heat removed by the two-phase thermal sub-system 120-150 from the DUT 160 in one or more cooling cycles, can be recycled to heat the DUT 160 by the two-phase thermal sub-system 120-150 during one or more heating cycles. The two-phase thermal sub-system 120-150 can include a condenser unit 120, a test site 130, a thermal control unit 140, and optionally a manifold 150. The condensing unit 120 can include a compressor 122, a condenser 124, and one or more control valves 126, 128. The test site 130 can include one or more control valves 132, 134, an evaporator (e.g., two phase thermal plate) 136, and optionally a thermal interface mount (TIM) 138. The thermal control unit 140 can control operation of the compressor 122, condenser 124, the one or more control valves 126, 128 of the condensing unit 120, and the one or more control valves 132, 134 of the test site 130 during one or more cooling modes and one or more heating modes in coordination with one or more functional tests of the DUT 160 by the DUT functional tester 110. The manifold 150 can include one or more liquid and one or more gaseous couplings between the condensing unit 120 and the test site 130.

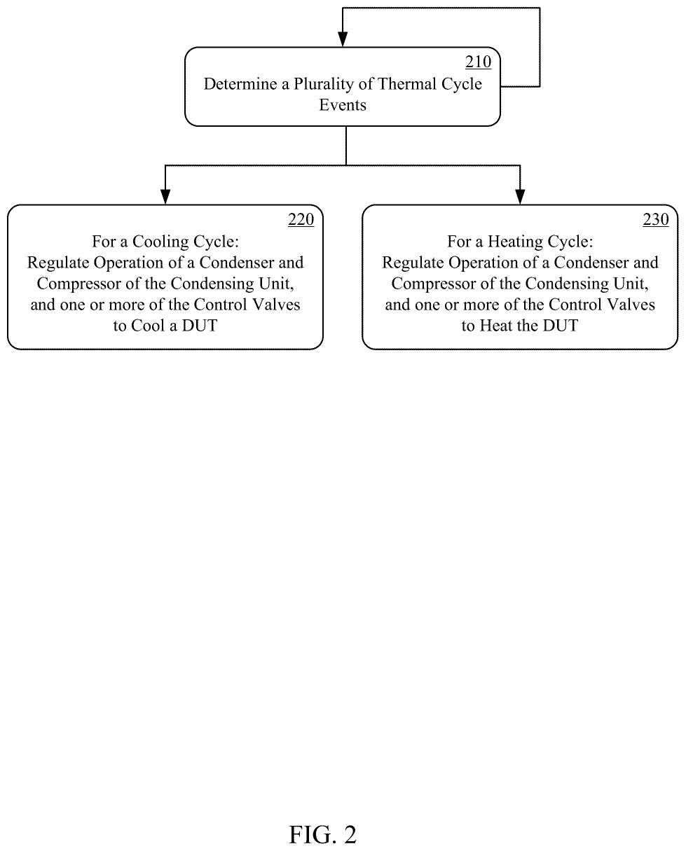

Operation of the two-phase thermal sub-system 120-150 will be further explained with reference to FIG. 2. The thermal control unit 140 can be configured to determine a plurality of thermal cycle events, at 210. For example, the thermal control unit 140 can receive data and/or one or more control signals from the DUT functional tester 110 indicating a cooling or heating mode and one or more parameters of the cooling or heating mode. The one or more parameters can include but are not limited to temperature, time and the like. For a cooling cycle, the thermal control unit 140 can be configured to regulate operation of the compressor 122 and condenser 124 of the condensing unit, and one or more of the control valves 126, 128, 132, 134 of the condensing unit 120 and/or the test site 130 to cool the DUT 110, at 220. For a heating cycle, the thermal control unit 140 can be configured to regulate operation of the compressor 122 and condenser 124 of the condensing unit, and one or more of the control valves 126, 128, 132, 134 of the condensing unit 120 and/or the test site 130 to heat the DUT 110, at 230. The processes 210-230 can be iteratively performed to implement each of one or more cooling and heating cycles during testing of the DUT 110.

For example, the compressor 122 can be regulated to convert low-pressure suction refrigerant from the test site 130 to high pressure and high temperature gas by compression, and the condenser 124 can convert the hot gas to a high-pressure liquid by condensation. The valves 126, 128 of the condensing unit 120 can be regulated to control the refrigerant superheat and pressure to the compressor 122. The manifold 150 can include a liquid refrigerant line coupled between the condenser 124 and the evaporator 136, a hot gas supply line coupled between the compressor and the evaporator 136, a hot gas return line coupled between the condenser 124 and the evaporator, and a suction line coupled between the compressor 122 and the evaporator 132. The valves 132, 134 of the test site 130 control the flow of liquid refrigerant and hot gas refrigerant to achieve a given test temperature of the DUT 160. Cooling by the evaporator 136 is achieved by lowering the pressure and temperature of the liquid refrigerant by the expansion valve 132 before entering the evaporator 136. Heating by the evaporator 136 is achieved by the flow of the hot gas supply regulated by the second valve 134 of the test site 130. The optional thermal interface material 138, disposed between the evaporator 136 and the DUT 150, can reduce the thermal contact resistance.

In an optional aspect of the present technology, the evaporator 136 can include a plurality of zones that can provide separate heating and cooling of corresponding zones in the DUT 160. For example, a first zone of the evaporator 136 can provide cooling to a corresponding first zone of the DUT 160, while a second zone of the evaporator 136 can provide heating to a corresponding second zone of the DUT 160. The plurality of zones of the evaporator 136 can be separated from each other by respective thermal barriers. Furthermore, each zone of the evaporator 136 can include separate respective flow channels. Furthermore, separate sets of expansion values 132 and second valve 134 can be provide for each separate flow channel.

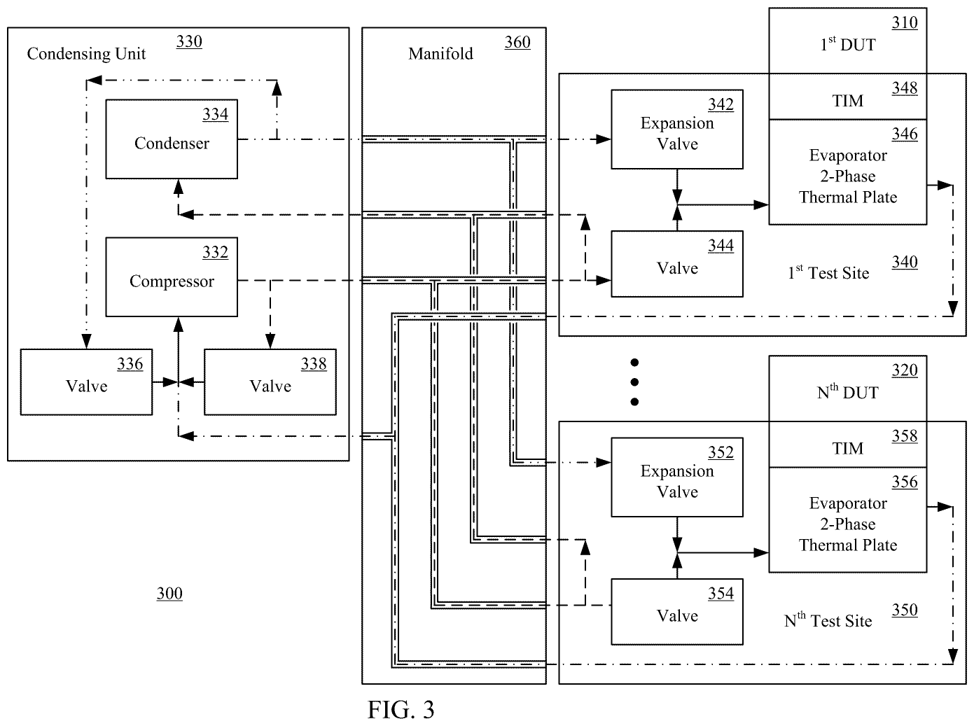

Referring now to FIG. 3, a test system, in accordance with aspects of the present technology, is shown. The test system 300 is configured for testing a plurality of devices under test (DUTs) 310-320. The test system 300 illustrated in FIG. 3 is substantially similar to the single DUT test system 100 illustrated in FIG. 1. The test system 300 can include one or more functional testers (not shown) and a two-phase thermal sub-system 330-360. The one or more functional testers can be coupled to a plurality of DUTs 310, 320 to perform one or more tests of one or more functions of the DUTs 310, 320. For example, the functional testers can be coupled to a plurality of semiconductor devices under test, such as but not limited to memory devices, processing units or the like, to perform one or more tests, such as but not limited to performing various memory access functions, one or more computation functions and or the like, of the semiconductor devices.

The two-phase thermal sub-system 330-360 can be configured to cool the plurality of DUTs 310, 320 in a cooling mode, and heat the DUTs 310, 320 in a heating mode during one or more of the functional tests of the DUTs 310, 320. The heat removed by the two-phase thermal sub-system 330-360 from the DUTs 310, 320 in one or more cooling modes, can be recycled to heat the DUTs 310, 320, by the two-phase thermal system 330-360, during one or more heating modes. The two-phase thermal sub-system 330-360 can include a condensing unit 330, a plurality of test sites 340, 350, a thermal control unit (not shown), and optionally a manifold 360. The condensing unit 330 can include a compressor 332, a condenser 334, and one or more control valves 336, 338. The test sites 340, 350, can each include one or more control valves 342, 344, 352, 354, an evaporator (e.g., two phase thermal plate) 346, 356, and optionally a thermal interface material (TIM) 348, 358. The function of the test system 300 illustrated in FIG. 3, is substantially similar to the single DUT test system 100 illustrated in FIG. 1. The thermal control unit can control operation of the compressor 332, condenser 334, the one or more control valves 336, 338 of the condensing unit 330, and the one or more control valves 342, 344, 352, 354 of the plurality of test sites 340, 350 during one or more cooling modes and one or more heating modes in coordination with one or more functional tests of the DUTs 310, 320 by the DUT functional tester. The manifold 360 can include one or more liquid and one or more gaseous couplings between the condensing unit 330 and the plurality of test sites 340, 350. The control valves 324, 326, 334, 336 control the flow of liquid refrigerant and hot gas refrigerant to achieve a given test temperature for each of the respective DUTs 310, 320. The temperature of each DUT 310, 320 can be controlled by application of respective cooling and heating cycles to the plurality of DUTs. Alternatively, the temperature of each DUT 310, 320 can be controlled by application of different cooling and heating cycles at different times to different DUTs 310, 320.

In another implementation, the control valve 342, 344, 352, 354 can be shared by the plurality of test sites 320, 330, instead of each test site having individual control valves. When the control valves are shared by the plurality of test sites 320, 330, the temperature of each DUT is controlled for simultaneously application of respective cooling and heating cycles. The temperature of each DUT cannot be readily controlled for application of different cooling and heating cycles. Furthermore, it may be more difficult or not possible to achieve the same temperature of each DUT, when the control valves are shared by the plurality of test sites.

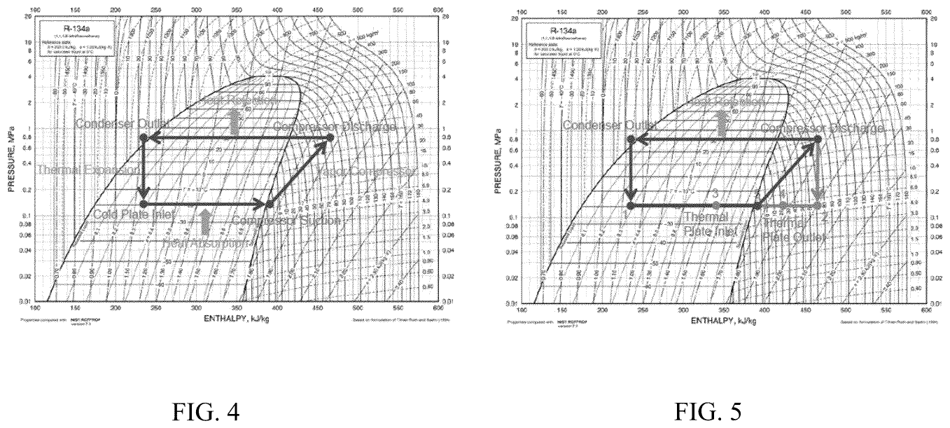

Referring now to FIGS. 4, a relationship between enthalpy and pressure for a DUT cooling cycle, according to the conventional art, is shown. As illustrated, the compressor compresses the gas received at the input of the compressor (e.g., compressor suction) and the output of the compressor (e.g., compressor discharge). Heat is removed from the gas between the input of the condenser and the output of the condenser. Thermal expansion of the condensed gas by the expansion valve reduces the temperature of the gas. The cool gas flowing through the evaporator acts to cool the temperature of the DUT. In the conventional art, heating is separately provided by hot fluid or a heater. In the case of using a heater to heat air, the system adds thermal resistance between the evaporator and the DUT. In the case of using hot fluid for heating the DUT, separate circulation and heating equipment are required. Additionally, the heater and/or liquid circulation requirement in conventional system increases the cost of the test system and increases the power consumption by the test system.

Referring now to FIG. 5, a relationship between enthalpy and pressure for DUT cooling and heating cycles, according to the present technology, is shown. Again, during cooling, the compressor compresses the gas between the input of the compressor (e.g., compressor suction) and the output of the compressor (e.g., compressor discharge). Heat is removed from the gas between the input of the condenser and the output of the condenser. Thermal expansion of the condensed gas by the expansion valve reduces the temperature of the gas. The cool gas flowing through the evaporator acts to cool the temperature of the DUT. However, during heating, a portion of the compressor discharge vapor is directed to the evaporator as a heating source for the DUT. As illustrated in FIG. 6, a portion of the compressor discharge vapor is thermally expanded to low pressure and high temperature vapor, state point 2, as a heating source, while the rest of compressor vapor discharge goes to condenser and is condensed to a liquid. The liquid is thermally expanded to low pressure and low temperature, state point 1, as a cooling source. The control valves 134, 136, 324, 326, 334, 336 of the test site(s) 130, 320, 330 are configured to provide a thermal inlet to the evaporators 132, 322, 332, between state points 1 and 2. For high heat load testing, the evaporator inlet is controlled close to state point 1. For low load testing, the evaporator inlet is operated close to state point 2. The control valves 122, 124, 312, 324 of the condensing unit 120, 310 are configured for control of superheat of the compressor suction. If the evaporator 132 322 has higher superheat than the compressor suction requirement, the first control valve 126, 316 can be opened to decrease the superheat. If the evaporator 132, 322 has a lower superheat than the compressor suction requirement, the second control valve can be opened to increase the superheat.

As compared to a separate heater of the conventional system, the two-phase thermal system has a lower overall thermal resistance and low time constant between the evaporator and the DUTs. As compared to separate heating and cooling fluid systems, the two-phase thermal system does not require an intermediate medium for colling and heating between the evaporator and medium recirculation.

Aspects of the present technology advantageously simplify the system architecture without the utilization of a separate heater for heating air or a fluid. Aspects of the present technology advantageously reduce the cost of the test equipment. The test equipment, in accordance with the system architecture of the present technology, can advantageously be utilized for testing high speed interfaces, such as but not limited to peripheral component interface express (PCIe) interfaces, test devices having optical interfaces, and or the like. The test equipment, in accordance with the system architecture of the present technology, can also advantageously reduce the test pattern memory of the tester.

The following examples pertain to specific technology embodiments and point out specific features, elements, or steps that may be used or otherwise combined in achieving such embodiments.

Example 1 includes a two-phase thermal system for controlling thermal cycles of a device under test comprising: a compressor; a condenser; an evaporator configured for thermally coupling to the device under tests; a first set of control valves configured to regulate the addition of refrigerant liquid from the condenser and refrigerant hot gas from the compressor to suction refrigerant from the evaporator; and a second set of control valves configured to regulate the supply of the refrigerant liquid from the condenser and the refrigerant hot gas from the compressor to the evaporator.

Example 2 includes the two-phase thermal system for controlling thermal cycles of the device under test of Example 1, further comprising: a manifold including: a liquid line to couple the refrigerant liquid from the condenser to an expansion valve of the second set of control valves; a hot gas supply line to couple hot gas from the compressor to a second valve of the second set of control valves; and a suction line to couple suction refrigerant from the evaporator to the compressor.

Example 3 includes the two-phase thermal system for controlling thermal cycles of the device under test of Example 1, further comprising: a thermal control unit configured to regulate operation of the compressor, the condenser, the first set of control valves and the second set of control valves to selectively cool and heat the device under test.

Example 4 includes the two-phase thermal system for controlling thermal cycles of the device under test of Example 3, further comprising: a manifold including: a liquid line to couple the refrigerant liquid from the condenser to an expansion valve of the second set of control valves; a hot gas supply line to couple hot gas from the compressor to a second valve of the second set of control valves; and a suction line to couple suction refrigerant from the evaporator to the compressor.

Example 5 includes the two-phase thermal system for controlling thermal cycles of the device under test of Example 4, wherein the manifold further includes: a hot gas return line to couple the hot gas, at the second valve of the second set of control valves, from the compressor to the condenser.

Example 6 includes the two-phase thermal system for controlling thermal cycles of the device under test of Example 1, further comprising: a thermal interface material disposed between the evaporator and the device under test.

Example 7 includes the two-phase thermal system for controlling thermal cycles of the device under test of Example 1, further comprising: the evaporator including separate flow channels in each of a plurality of zones; the second set of control valves configured to regulate the supply of the refrigerant liquid from the condenser and the refrigerant hot gas from the compressor to a first flow channel of the evaporator; and another second set of control valves configured to regulate the supply of the refrigerant liquid from the condenser and the refrigerant hot gas from the compressor to a second flow channel of the evaporator.

Example 8 includes the two-phase thermal system for controlling thermal cycles of the device under test of Example 1, further comprising a test site configured to couple the device under test to the evaporator.

Example 9 includes the two-phase thermal system for controlling thermal cycles of the device under test of Example 8, wherein the second set of control valves are disposed at the test site proximate the evaporator.

Example 10 includes the two-phase thermal system for controlling thermal cycles of the device under test of Example 8, wherein the test site is further configured to couple a functional test to the device under test.

Example 11 includes a test system comprising: a condensing unit including: a compressor; a condenser; and a first set of control valves configured to regulate the addition of refrigerant liquid from the condenser and refrigerant hot gas from the compressor to suction refrigerant from the evaporator; and a plurality of test sites, each test site including: an evaporator configured for thermally coupling to a device under tests; and a second set of control valves configured to regulate the supply of the refrigerant liquid from the condenser and the refrigerant hot gas from the compressor to the evaporator.

Example 12 includes the test system of Example 11, further comprising: one or more device under test functional testers for testing one or more functions of the devices under test coupled to the evaporator of each of the plurality of test sites.

Example 13 includes the system of Example 12, further comprising: a thermal control unit configured to regulate operation of the compressor, the condenser, the first set of control valves and the second set of control valves provide one or more cooling modes and one or more heating modes in coordination with one or more functional tests of the one or more device under test by the one or more device under test functional testers.

Example 14 includes the system of Example 13, further comprising: a manifold including: a liquid line to couple the refrigerant liquid from the condenser to an expansion valve of the second set of control valves; a hot gas supply line to couple hot gas from the compressor to a second valve of the second set of control valves; and a suction line to couple suction refrigerant from the evaporator to the compressor.

Example 15 includes a test system thermal control method comprising: determining a plurality of thermal cycle events; regulating operation of a condenser, a compressor and one or more control valves to cool one or more devices under test during one or more cooling cycles of the plurality of thermal cycle events; and regulating operation of the condenser, the compressor and the one or more control valves to heat the one or more devices under test during one or more heating cycles of the plurality of thermal cycle events.

Example 16 includes the test system thermal control method according to Example 15, wherein: determining a plurality of thermal cycle events includes; receiving data or one or more control signals indicating a cooling mode and one or more parameters of a cooling event; receiving data or one or more control signals indicating a heating mode and one or more parameters of a heating event; regulating operation during a cooling cycle includes regulating the condenser, the compressor and the one or more control valves based on the one or more control signals indicating the cooling mode and the one or more parameters of the cooling event; and regulating operation during a heating cycle includes regulating the condenser, the compressor and the one or more control valves based on the one or more control signals indicating the heating mode and the one or more parameters of the heating event.

Example 17 includes the test system thermal control method according to Example 15, wherein: regulating operation of the condenser, the compressor and the one or more control valves during a cooling cycle includes lowering the pressure and temperature of a liquid refrigerant by an expansion valve before entering an evaporator; and regulating operation of the condenser, the compressor and the one or more control valves during a heating cycle includes flowing hot gas, regulated by a second valve, from the compressor.

Example 18 includes the test system thermal control method according to Example 15, storing heat extracted by the compressor during one or more cooling cycles for use during one or more heating cycles.

Example 19 includes the test system thermal control method according to Example 15, further comprising regulating operation of the condenser, the compressor and the one or more control valves to cool a first device under test while heating a second device under test.

Example 20 include the test system thermal control method according to Example 15, further comprising regulating operation of the condenser, the compressor and the one or more control valves to cool a first zone of a device under test while heating a second zone of the same device under test.

The foregoing descriptions of specific embodiments of the present technology have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the present technology and its practical application, to thereby enable others skilled in the art to best utilize the present technology and various embodiments with various modifications as are suited to the particular use contemplated.

What is claimed is:

1. A two-phase thermal system for controlling thermal cycles of a device under test comprising:
a compressor;
a condenser;
an evaporator configured for thermally coupling to the device under tests;
a first set of control valves configured to regulate the addition of refrigerant liquid from the condenser and refrigerant hot gas from the compressor to suction refrigerant from the evaporator; and
a second set of control valves configured to regulate the supply of the refrigerant liquid from the condenser and the refrigerant hot gas from the compressor to the evaporator.

2. The two-phase thermal system for controlling thermal cycles of the device under test of claim 1, further comprising:
a manifold including:
a liquid line to couple the refrigerant liquid from the condenser to an expansion valve of the second set of control valves;
a hot gas supply line to couple hot gas from the compressor to a second valve of the second set of control valves; and
a suction line to couple suction refrigerant from the evaporator to the compressor.

3. The two-phase thermal system for controlling thermal cycles of the device under test of claim 1, further comprising:
a thermal control unit configured to regulate operation of the compressor, the condenser, the first set of control valves and the second set of control valves to selectively cool and heat the device under test.

4. The two-phase thermal system for controlling thermal cycles of the device under test of claim 3, further comprising:
a manifold including:
a liquid line to couple the refrigerant liquid from the condenser to an expansion valve of the second set of control valves;
a hot gas supply line to couple hot gas from the compressor to a second valve of the second set of control valves; and
a suction line to couple suction refrigerant from the evaporator to the compressor.

5. The two-phase thermal system for controlling thermal cycles of the device under test of claim 4, wherein the manifold further includes:
a hot gas return line to couple the hot gas, at the second valve of the second set of control valves, from the compressor to the condenser.

6. The two-phase thermal system for controlling thermal cycles of the device under test of claim 1, further comprising: a thermal interface material disposed between the evaporator and the device under test.

7. The two-phase thermal system for controlling thermal cycles of the device under test of claim 1, further comprising:
the evaporator including separate flow channels in each of a plurality of zones;
the second set of control valves configured to regulate the supply of the refrigerant liquid from the condenser and the refrigerant hot gas from the compressor to a first flow channel of the evaporator; and
another second set of control valves configured to regulate the supply of the refrigerant liquid from the condenser and the refrigerant hot gas from the compressor to a second flow channel of the evaporator.

8. The two-phase thermal system for controlling thermal cycles of the device under test of claim 1, further comprising a test site configured to couple the device under test to the evaporator.

9. The two-phase thermal system for controlling thermal cycles of the device under test of claim 8, wherein the second set of control valves are disposed at the test site proximate the evaporator.

10. The two-phase thermal system for controlling thermal cycles of the device under test of claim 8, wherein the test site is further configured to couple a functional test to the device under test.

11. A test system comprising:
a condensing unit including:
a compressor;
a condenser; and
a first set of control valves configured to regulate the addition of refrigerant liquid from the condenser and refrigerant hot gas from the compressor to suction refrigerant from the evaporator; and
a plurality of test sites, each test site including:
an evaporator configured for thermally coupling to a device under test; and
a second set of control valves configured to regulate the supply of the refrigerant liquid from the condenser and the refrigerant hot gas from the compressor to the evaporator.

12. The test system of claim 11, further comprising:
one or more device under test functional testers for testing one or more functions of the devices under test coupled to the evaporator of each of the plurality of test sites.

13. The system of claim 12, further comprising:
a thermal control unit configured to regulate operation of the compressor, the condenser, the first set of control valves and the second set of control valves provide one or more cooling modes and one or more heating modes in coordination with one or more functional tests of the one or more device under test by the one or more device under test functional testers.

14. The system of claim 13, further comprising:
a manifold including:
a liquid line to couple the refrigerant liquid from the condenser to an expansion valve of the second set of control valves;
a hot gas supply line to couple hot gas from the compressor to a second valve of the second set of control valves; and
a suction line to couple suction refrigerant from the evaporator to the compressor.

15. A test system thermal control method comprising:
determining a plurality of thermal cycle events;
regulating operation of a condenser, a compressor and one or more control valves to cool one or more devices under test during one or more cooling cycles of the plurality of thermal cycle events; and
regulating operation of the condenser, the compressor and the one or more control valves to heat the one or more devices under test during one or more heating cycles of the plurality of thermal cycle events.

16. The test system thermal control method according to claim 15, wherein:
determining a plurality of thermal cycle events includes;
receiving data or one or more control signals indicating a cooling mode and one or more parameters of a cooling event;
receiving data or one or more control signals indicating a heating mode and one or more parameters of a heating event;
regulating operation during a cooling cycle includes regulating the condenser, the compressor and the one or more control valves based on the one or more control signals indicating the cooling mode and the one or more parameters of the cooling event; and
regulating operation during a heating cycle includes regulating the condenser, the compressor and the one or more control valves based on the one or more control signals indicating the heating mode and the one or more parameters of the heating event.

17. The test system thermal control method according to claim 15, wherein:
regulating operation of the condenser, the compressor and the one or more control valves during a cooling cycle includes lowering the pressure and temperature of a liquid refrigerant by an expansion valve before entering an evaporator; and
regulating operation of the condenser, the compressor and the one or more control valves during a heating cycle includes flowing hot gas, regulated by a second valve, from the compressor.

18. The test system thermal control method according to claim 15, storing heat extracted by the compressor during one or more cooling cycles for use during one or more heating cycles.

19. The test system thermal control method according to claim 15, further comprising regulating operation of the condenser, the compressor and the one or more control valves to cool a first device under test while heating a second device under test.

20. The test system thermal control method according to claim 15, further comprising regulating operation of the condenser, the compressor and the one or more control valves to cool a first zone of a device under test while heating a second zone of the same device under test.
